(19) United States
(12) Patent Application Publication
(10) Pub. No.: US 2025/0158399 A1
(43) Pub. Date: May 15, 2025

(54) Power Grid Switching Circuit and Circuit System

(71) Applicant: Joulwatt Technology Co., Ltd., Hangzhou (CN)

(72) Inventor: Pitleong WONG, Hangzhou (CN)

(73) Assignee: Joulwatt Technology Co., Ltd., Hangzhou (CN)

(21) Appl. No.: 18/940,869

(22) Filed: Nov. 8, 2024

(30) Foreign Application Priority Data
Nov. 13, 2023 (CN) 202311504381.2

(51) Int. Cl. H02J 3/00; H02J 3/14

(52) U.S. Cl. CPC H02J 3/0012; H02J 3/14; H02J 2310/12

(57) ABSTRACT

A power grid switching circuit and a circuit system are provided. An on-off control module is configured to control safe on/off of a transistor switch module. Specifically, the on-off control module is configured to control the transistor switch module to turn off at a zero current and turn on at a zero voltage. In this way, the switching of a power grid and an electrical device is more intelligent and unrestricted in frequency. The power grid switching circuit is safe, highly efficient, and meets the intelligent, high-frequency, and easy-to-operate requirements of modern home control.

### CROSS-REFERENCE TO THE RELATED APPLICATIONS

This application is based upon and claims priority to Chinese Patent Application No. 202311504381.2, filed on Nov. 13, 2023, the entire contents of which are incorporated herein by reference.

### TECHNICAL FIELD

The present disclosure relates to the technical field of power electronics, and in particular to a power grid switching circuit and a circuit system.

### BACKGROUND

Mechanical switches are usually used in a household power grid system to control the on/off of the power grid and electrical devices. For example, multiple mechanical switches can be used to control the on/off of multiple electrical devices, respectively. The mechanical switches can be manually triggered to control the on/off of the electrical devices.

With the development of home intelligence, electronic switches such as field-effect transistors (FETs) and transistors tend to replace mechanical switches. However, when electronic switches are used instead of mechanical switches, there are safety and energy consumption issues during the on-off of electronic switches. Therefore, there is a need for a safe and low-consumption control solution to ensure that electronic switches replacing mechanical switches meet the requirements of home circuit systems.

Therefore, it is necessary to provide an improved technical solution to address the above technical problems existing in the prior art.

### SUMMARY

In view of this, an objective of the present disclosure is to provide a power grid switching circuit and a circuit system to solve the technical problems of safety and energy consumption existing in the prior art.

The present disclosure provides a power grid switching circuit, where an alternating current (AC) input is provided to supply power to an electrical device through a switch module and a current transformer; the power grid switching circuit includes: an on-off control module, configured to output an on/off control signal to control an on/off state of the switch module; the switch module, the current transformer, and the electrical device form a power loop circuit when the switch module is in an on state; and the on-off control module is configured to control the switch module to turn off at a current extremum of the power loop circuit, so as to disconnect the power loop circuit, the current extremum being zero or close to zero.

Preferably, the switch module includes a field-effect transistor (FET) or bipolar transistor device.

Preferably, the on-off control module includes a current detection circuit; the current detection circuit is configured to detect a current at a node in the power loop circuit; and when the current detected reaches the current extremum, the switch module is turned off.

Preferably, the on-off control module includes a voltage detection circuit; the voltage detection circuit is configured to detect voltages at two connection nodes of the switch module connected to the power loop circuit; and when a voltage difference between the two nodes is less than a voltage threshold, the switch module is turned off.

Preferably, the switch module includes a first transistor and a second transistor connected in series; body diode directions of the first transistor and the second transistor are opposite; and the on-off control module is configured to control a finally disconnected transistor of the first transistor and the second transistor to turn off at the current extremum, so as to disconnect the power loop circuit.

Preferably, the on-off control module is configured to control the first transistor to turn off when receiving a turn-off enable signal and control the second transistor to turn off at the current extremum.

Preferably, when the on-off control module controls the first transistor to turn off, the second transistor remains on; the AC input forms the power loop circuit through the second transistor, a parasitic diode of the first transistor, the current transformer, and the electrical device; and when a current in the power loop circuit reaches the extremum, the on-off control module controls the second transistor to turn off.

Preferably, the on-off control module includes a first on-off control circuit and a second on-off control circuit; the first on-off control circuit is configured to generate a first on/off signal based on a first node voltage and a first reference voltage to control an on/off state of the first transistor; the second on-off control circuit is further configured to generate a second on/off signal based on a second node voltage and a second reference voltage to control an on/off state of the second transistor; a terminal of the first transistor connected to the second transistor serves as a common connection terminal; and a voltage at another terminal of the first transistor serves as the first node voltage, while a voltage at another terminal of the second transistor serves as the second node voltage.

Preferably, the common connection terminal of the first transistor connected to the second transistor is connected to a reference ground terminal; the first reference voltage is set to be less than a voltage of the reference ground terminal; and the second reference voltage is set to be larger than the voltage of the reference ground terminal.

Preferably, the first on-off control circuit includes a first error circuit and a first switch; the first error circuit is configured to receive the first node voltage and the first reference voltage and generate a first error signal; the first switch is turned on when the turn-off enable signal is valid; the second on-off control circuit includes a second error circuit and a second switch; the second error circuit is configured to receive the second node voltage and the second reference voltage and generate a second error signal; and the second switch is turned on when the turn-off enable signal is valid.

Preferably, the first on-off control circuit includes a first error circuit; the first error circuit is configured to receive the first node voltage and the first reference voltage and generate a first error signal; the first error circuit starts working when the turn-off enable signal is valid; the second on-off control circuit includes a second error circuit; the second error circuit is configured to receive the second node voltage and the second reference voltage and generate a second error signal; and the second error circuit starts working when the turn-off enable signal is valid.

Preferably, the first on-off control circuit includes a first pull-down circuit, and the second on-off control circuit includes a second pull-down circuit; the first pull-down circuit is connected between an output terminal of the first on-off control circuit and a control terminal of the first transistor; when a control terminal voltage of the first transistor is detected to drop to a threshold voltage, the first pull-down circuit is turned on; the second pull-down circuit is connected between an output terminal of the second on-off control circuit and a control terminal of the second transistor; and when a control terminal voltage of the second transistor is detected to drop to the threshold voltage, the second pull-down circuit is turned on.

Preferably, the first on-off control circuit includes a first resistor network, and the second on-off control circuit includes a second resistor network; the first resistor network includes a first resistor and a switch connected in series with the first resistor, and a series branch is connected in parallel with the first transistor; the second resistor network includes a second resistor and a switch connected in series with the second resistor, and a series branch is connected in parallel with the second transistor; when the first transistor is turned off, the switch connected in series with the second resistor is turned on; and when the second transistor is turned off, the switch connected in series with the first resistor is turned on.

Preferably, the on-off control module includes a turn-on control circuit; the turn-on control circuit is connected to control terminals of the first transistor and the second transistor; the turn-on control circuit is configured to pull up control terminal voltages of the first transistor and the second transistor when receiving a turn-on enable signal, so as to control the first transistor and the second transistor to turn on; and the turn-on control circuit is further configured to stop the pull-up of the control terminal voltages of the first transistor and the second transistor when receiving a turn-off enable signal.

Preferably, the turn-on control circuit includes a terminal voltage detection circuit; and when the terminal voltage detection circuit detects that two power terminal voltages of the first transistor and/or the second transistor reach or approach a zero voltage value, the turn-on control circuit controls the first transistor and/or the second transistor to turn on.

Preferably, the on-off control module is configured to control the first transistor and the second transistor to turn off at the current extremum when receiving a turn-off enable signal.

Preferably, when the on-off control module receives the turn-off enable signal, after a control terminal voltage of the first transistor decreases, both the first transistor and the second transistor remain on; and

the AC input forms the power loop circuit through the second transistor, the first transistor, the current transformer, and the electrical device; and when a current in the power loop circuit reaches the extremum and a control terminal voltage of the second transistor decreases, the on-off control module controls the first transistor and the second transistor to turn off.

In a second aspect, the present disclosure provides a circuit system, configured to receive an AC input and form a power loop circuit to supply power to an electrical device, and including the above-mentioned power grid switching circuit, where the circuit system is configured to generate the turn-on enable signal/turn-off enable signal based on a working state of the system, such that the power grid switching circuit performs a switching operation based on the turn-on enable signal/turn-off enable signal.

In the power grid switching circuit control solution of the present disclosure, the on-off control module controls the safe on/off of the transistor switch module. The on-off control module controls the transistor switch module to turn off at a zero current and turn on at a zero voltage, making the switching of the power grid and electrical device safer, more intelligent, unrestricted in frequency, and with a longer lifespan. The power grid switching circuit in the present disclosure is safe, efficient, and meets the intelligent, high-frequency, and easy-to-operate requirements of modern home control.

### BRIEF DESCRIPTION OF THE DRAWINGS

FIG. 1 is a block diagram of a power grid switching circuit according to the present disclosure;

FIG. 2 is a specific block diagram of the power grid switching circuit according to the present disclosure;

FIG. 3 is a first implementation circuit diagram of an on-off control module shown in FIG. 2 according to the present disclosure;

FIG. 4 is a second implementation circuit diagram of the on-off control module shown in FIG. 2 according to the present disclosure;

FIG. 5 is a third implementation circuit diagram of the on-off control module shown in FIG. 2 according to the present disclosure;

FIG. 6 is a fourth implementation circuit diagram of the on-off control module shown in FIG. 2 according to the present disclosure; and

FIG. 7 is a fifth implementation circuit diagram of the on-off control module shown in FIG. 2 according to the present disclosure.

### DETAILED DESCRIPTION OF THE EMBODIMENTS

The preferred embodiments of the present disclosure are described in detail below with reference to the drawings, but the present disclosure is not limited to these embodiments. The present disclosure covers any substitution, modification, equivalent method and solution made within the spirit and scope of the present disclosure.

For a better understanding of the present disclosure, the specific details of the following preferred embodiments of the present disclosure are explained hereinafter in detail, while the present disclosure can also be fully understood by those skilled in the art without the description of these details.

The present disclosure is described in detail by giving examples with reference to the drawings. It should be noted that the drawings are simplified and do not use an accurate proportion, that is, the drawings are merely for the objectives of conveniently and clearly assisting in illustrating embodiments of the present disclosure.

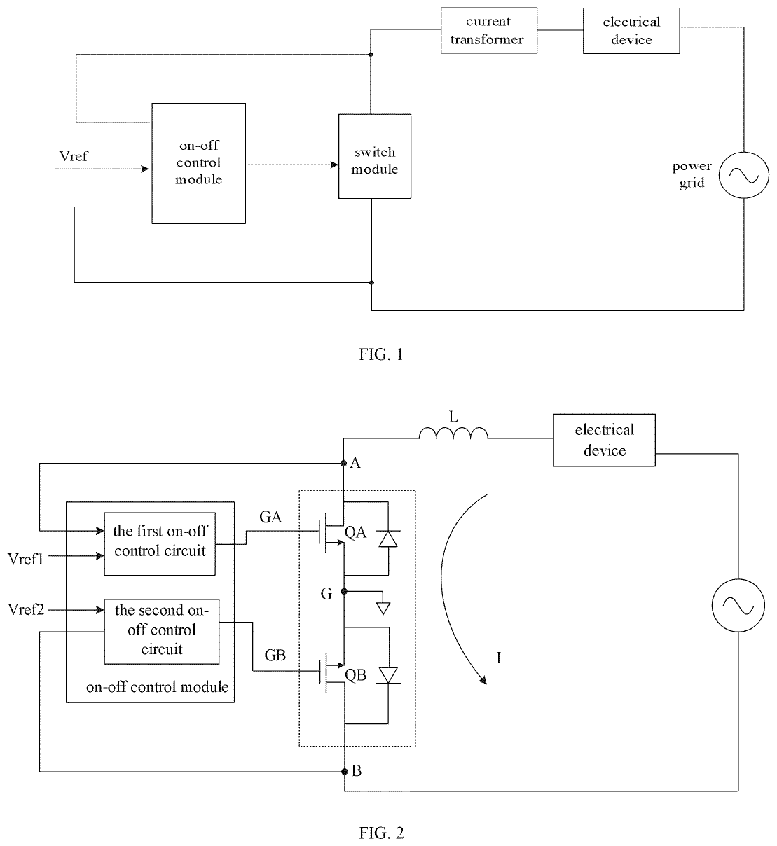

FIG. 1 is a block diagram of a power grid switching circuit according to the present disclosure; FIG. 2 is a specific block diagram of the power grid switching circuit according to the present disclosure; and FIG. 3 is a first implementation circuit diagram of an on-off control module shown in FIG. 2 according to the present disclosure. As shown in FIG. 1, in an embodiment, the power grid switching circuit includes a switch module and a current transformer. An alternating current (AC) input of a power grid is configured to supply power to an electrical device through the switch module and the current transformer, and form a power loop circuit when the switch module is in an on state. The current transformer can be an equivalent parasitic transformer in a circuit.

The switch module includes first transistor QB and second transistor QA connected in series. Body diode directions of the first transistor and the second transistor are opposite. Here, the first transistor and the second transistor are either field-effect transistors (FETs) or bipolar transistors. FETs are used in this embodiment. The on-off control module is configured to control the switch module to turn off at a current extremum of the power loop circuit, so as to disconnect the power loop circuit, where the current extremum is zero or close to zero. The on-off control module is configured to control a finally disconnected transistor of the first transistor and the second transistor to turn off at the current extremum, so as to disconnect the power loop circuit. For example, the on-off control module is configured to control the two transistors to turn off at the current extremum or to first control one transistor to turn off and then control the other transistor to turn off at the current extremum.

In this embodiment, the first transistor QB is controlled to turn off when receiving a turn-off enable signal, and the second transistor QA is controlled to turn off at the current extremum, where the current extremum is zero or close to zero. Specifically, the on-off control module controls the first transistor to turn off while the second transistor remains on. The AC input forms the power loop circuit through the second transistor, the body diode of the first transistor, the current transformer, and the electrical device. When a current in the power loop circuit reaches the extremum, the on-off control module controls the second transistor to turn off. Here, due to the alternating voltage and current of the power grid, the current in the power loop circuit will vary from large to small or from small to large. The turn-off enable signal is acquired based on a working state of the system. For example, when the system needs to stop or when a system failure occurs, the turn-off enable signal is generated. The turn-off enable signal effectively indicates that the power loop circuit needs to stop supplying power to the electrical device. According to the above solution, in a certain direction of the AC current in the power grid, as shown in FIG. 2, after the first transistor QB is turned off, its current can continue to flow through the body diode of the first transistor, and the first transistor can be safely turned off. Afterwards, due to the high current passing through the second transistor QA, if the second transistor is directly turned off, the large induced energy generated by the current transformer will break down the second transistor. Therefore, the second transistor is turned off only when the current in the power loop circuit reaches the extremum, such as zero or close to zero. The design can safely turn off the second transistor, thereby achieving the goal of safe turn-off of the entire system. The power grid can provide a 220 V AC or 110 V AC, etc.

As shown in FIGS. 2 and 3, the on-off control module is configured to control on/off states of the first transistor and the second transistor. The on-off control module includes a first on-off control circuit and a second on-off control circuit. The first on-off control circuit is configured to generate a first on/off signal based on a first node voltage and first reference voltage Vref1 to control the on/off state of the first transistor. The second on-off control circuit is configured to generate a second on/off signal based on a second node voltage and second reference voltage Vref2 to control the on/off state of the second transistor. A terminal of the first transistor connected to the second transistor serves as a common connection terminal, such as node G. A voltage another terminal of the first transistor serves as the first node voltage, such as a node A voltage, and a voltage at another terminal of the second transistor serves as the second node voltage, such as a node B voltage.

Preferably, the common connection terminal of the first transistor connected to the second transistor is connected to a reference ground terminal. The first reference voltage is set to be less than a voltage of the reference ground terminal, and the second reference voltage is set to be larger than the voltage of the reference ground terminal. Here, a difference between the first reference voltage and the voltage of the reference ground terminal can be set as a first preset value, which is any value within 0-30 mv. A difference between the second reference voltage and the voltage of the reference ground terminal can be set as a second preset value, which is any value within 0-30 mv. Preferably, an absolute value of the difference between the first reference voltage and the voltage of the reference ground terminal and an absolute value of the difference between the second reference voltage and the voltage of the reference ground terminal can be set to be equal.

As shown in FIG. 3, the first on-off control circuit includes a first error circuit and first switch S1. The first error circuit is configured to receive the first node voltage VA and the first reference voltage Vref1 and generate a first error signal. The first switch S1 is on when the turn-off enable signal (such as signal of EN) is valid. The second on-off control circuit includes a second error circuit and a second switch. The second error circuit is configured to receive the second node voltage and the second reference voltage and generate a second error signal. The second switch is turned on when the turn-off enable signal is valid. The circuit structure of the second on-off control circuit is the same as that of the first on-off control circuit, and only the structural diagram of the first on-off control circuit is shown here. The first error circuit includes a first error amplifier, and the second error circuit includes a second error amplifier. The first node voltage is input to a positive input terminal of the first error amplifier, and the first reference voltage is input to a negative input terminal of the first error amplifier. For the second error amplifier, the second node voltage is input to a positive input terminal of the first error amplifier, and the second reference voltage is input to the negative input terminal of the first error amplifier.

As shown in FIG. 3, the on-off control module includes turn-on control circuits. The turn-on control circuits are connected to control terminals of the first transistor and the second transistor. Here, the first on-off control circuit and the second on-off control circuit each include one turn-on control circuit. When receiving a turn-on enable signal, such as one generated when the system is started, the turn-on control circuit pulls up control terminal voltages of the first transistor and the second transistor to control the first transistor and the second transistor to turn on. As shown in FIG. 3, switch S2 is connected to voltage source VDD. When the turn-on enable signal is valid, switch S2 is on, and the control terminal voltage of the first transistor is pulled up, allowing the first transistor to turn on. Afterwards, when receiving the turn-off enable signal, if the turn-off enable signal is invalid (non-signal of EN), the turn-on control circuit stops the pull-up of the control terminal voltage of the first transistor.

According to the above circuit structure, when the system generates a turn-off enable signal, the first error amplifier and the first switch start to operate. As shown in FIG. 2, when the current direction is from point A to point B, the output of the second error amplifier is low, the first transistor QB is turned off, the second transistor QA remains on, and the current continues to form a power loop circuit through the body diode. When the current direction in the power loop circuit changes from high to low, the current in the second transistor QA decreases. When the node A voltage reaches the second reference voltage, the control terminal voltage of the second transistor QA decreases and the second transistor is turned off. At this point, due to the low system current, the second transistor can be safely turned off.

Preferably, as shown in FIG. 3, in the embodiment of the present disclosure, the first on-off control circuit includes a first pull-down circuit, and the second on-off control circuit includes a second pull-down circuit. The first pull-down circuit is connected between an output terminal of the first on-off control circuit and the control terminal of the first transistor. When the control terminal voltage of the first transistor is detected to drop to a threshold voltage, the first pull-down circuit is turned on. The second pull-down circuit is connected between an output terminal of the second on-off control circuit and the control terminal of the second transistor. When the control terminal voltage of the second transistor is detected to drop to the threshold voltage, the second pull-down circuit is turned on. Here, the threshold voltage can be zero. The pull-down circuit can be a controllable switch transistor, or a series circuit of a controllable switch transistor and a resistor, or a current source. When the control terminal voltage of the first transistor is detected to drop close to the threshold, a trigger signal is generated to turn on the first pull-down circuit, so as to pull down the control terminal voltage of the first transistor. The design can reduce system power consumption and avoid energy consumption caused by a residual voltage after the power supply is stopped.

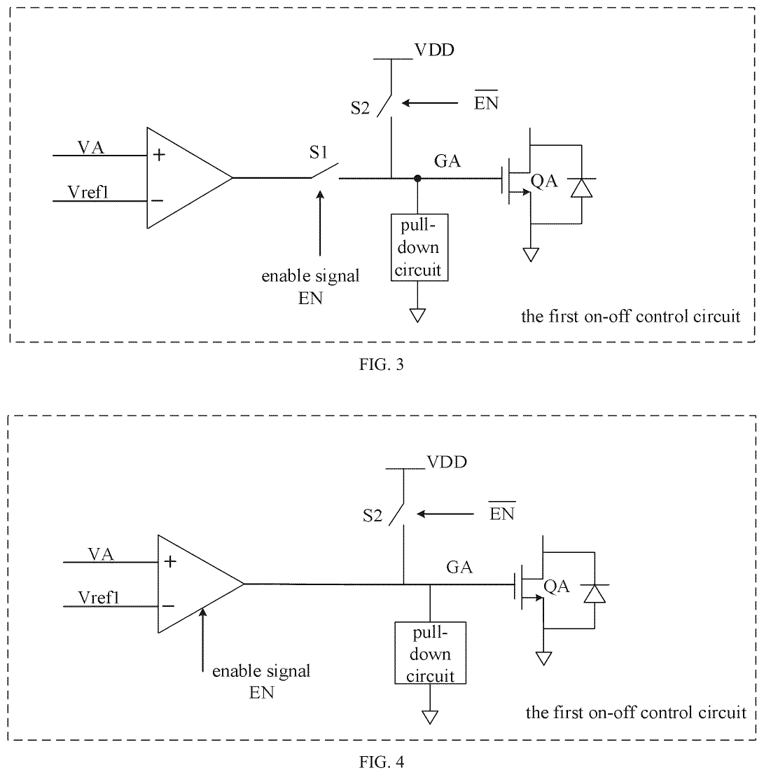

FIG. 4 is a second implementation circuit diagram of the on-off control module shown in FIG. 2 according to the present disclosure. Unlike the embodiment shown in FIG. 3, in this embodiment, the first on-off control circuit includes a first error circuit. The first error circuit is configured to receive the first node voltage and the first reference voltage, and generate the first error signal. The first error circuit starts working when the turn-off enable signal is valid. The second on-off control circuit includes a second error circuit. The second error circuit is configured to receive the second node voltage and the second reference voltage, and generate the second error signal. The second error circuit starts working when the turn-off enable signal is valid. That is, the first error circuit and the second error circuit are directly enabled or disabled by the turn-off enable signal. In this embodiment, the turn-off enable signal EN is directly transmitted to an input terminal of the error amplifier, thereby starting the operation of the error amplifier after the system receives a turn-off command. Similarly, this embodiment can also safely turn off the first transistor and the second transistor.

FIG. 5 is a third implementation circuit diagram of the on-off control module shown in FIG. 2 according to the present disclosure. Unlike the embodiment shown in FIG. 3, in this embodiment, the first on-off control circuit includes a first resistor network, and the second on-off control circuit includes a second resistor network. The first resistor network includes a first resistor and a switch connected in series with the first resistor, and a series branch is connected in parallel with the first transistor. The second resistor network includes a second resistor and a switch connected in series with the second resistor, and a series branch is connected in parallel with the second transistor. When the first transistor is turned off, the switch connected in series with the second resistor is turned on. When the second transistor is turned off, the switch connected in series with the first resistor is turned on. In this embodiment, the values of the first resistor and the second resistor are set. When the current in the power loop circuit is small, the first resistor or second resistor is connected in parallel with an on resistor of the transistor to obtain a parallel resistance value. In this way, the turn-on voltage drop of the first transistor or the second transistor is actively controlled, such that the first node voltage and the second node voltage can reach the required voltage level.

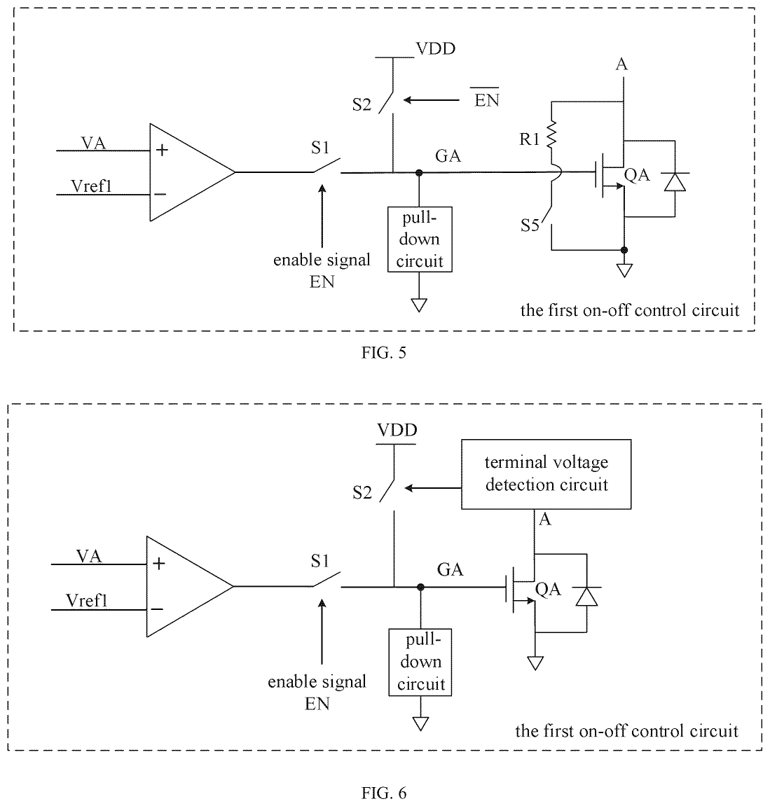

FIG. 6 is a fourth implementation circuit diagram of the on-off control module shown in FIG. 2 according to the present disclosure. Unlike the embodiment shown in FIG. 3, in this embodiment, the turn-on control circuit includes a terminal voltage detection circuit. When the terminal voltage detection circuit detects that two power terminal voltages of the first transistor and/or the second transistor reach or approach a zero voltage value, the turn-on control circuit controls the first transistor and/or the second transistor to turn on. This embodiment can control two transistors to turn on at or close to the zero voltage value, thereby reducing on/off power consumption to a greater extent.

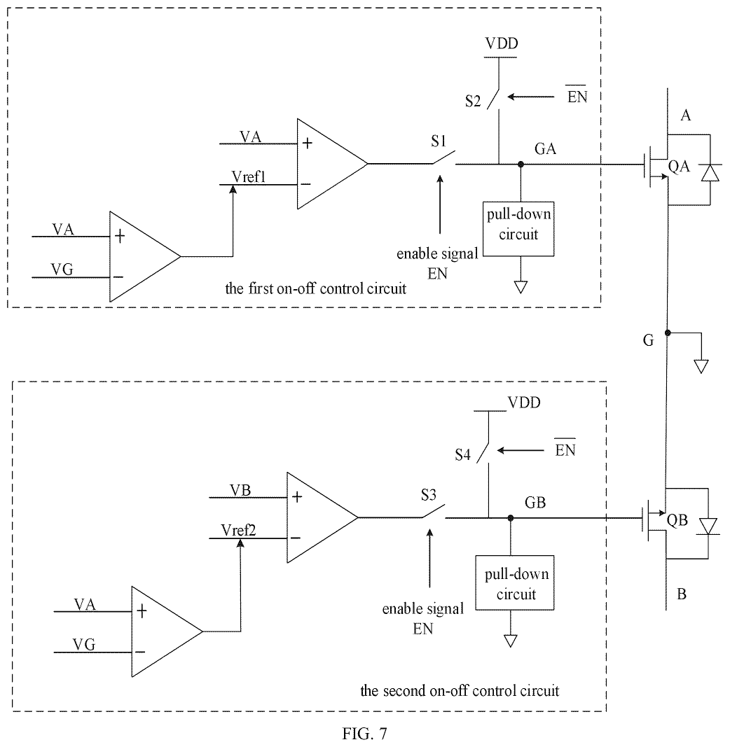

FIG. 7 is a fifth implementation circuit diagram of the on-off control module shown in FIG. 2 according to the present disclosure. In FIG. 7, the switch module includes a first transistor and a second transistor connected in series, and body diode directions of the first and second transistors are opposite. The on-off control module is configured to control the first transistor and the second transistor to turn off at the current extremum when receiving a turn-off enable signal, where the current extremum is zero or close to zero. Specifically, the on-off control module receives a turn-off enable signal such as enable signal EN. After the control terminal voltage of the first transistor such as QB decreases, both the first transistor and the second transistor remain on. The AC input forms a power loop circuit through the second transistor, the first transistor, the current transformer, and the electrical device. When the current in the power loop circuit reaches the extremum and the control terminal voltage of the second transistor decreases, the on-off control module controls the first transistor and the second transistor to turn off.

In the embodiment shown in FIG. 7, the circuit structures of the first on-off control circuit and the second on-off control circuit are partially similar to those of the embodiment in FIG. 3, and the similar parts will not be repeated here. The difference between the first on-off control circuit and the second on-off control circuit is as follows. The first on-off control circuit further includes a first comparator for comparing the first node voltage with the voltage of the reference ground terminal to control the magnitude of the first reference voltage. The second on-off control circuit further includes a second comparator for comparing the second node voltage with the voltage of the reference ground terminal to control the magnitude of the second reference voltage. The two comparators are configured to distinguish the current direction and set the first reference voltage to a positive or negative value to control the control terminal voltage of one of the transistors. When the control terminal voltage of one of the transistors is low, the transistor is not immediately turned off. When the control terminal voltage of the other transistor becomes low, both the first transistor and the second transistor are turned off.

Similarly, in the embodiment of the present disclosure, the first transistor and the second transistor are either FETs or bipolar transistors. In this embodiment, the first transistor and the second transistor are turned off simultaneously to avoid significant losses to the body diodes under high current conditions, further reducing system power consumption and improving efficiency.

In the above embodiment, the on-off control module controls the turn-off of the two transistors by measuring the error between the node voltage and the reference voltage. Those skilled in this field know that other methods can also be used. For example, the on-off control module includes a current detection circuit, which is configured to detect the currents of the first transistor or the second transistor. When the currents reach or approach the current extremum, namely zero, the first transistor and the second transistor are turned off separately by triggering with a short pulse signal. The design can also achieve the goal of safely turning off the two transistors.

In addition, the on-off control module can also adopt a voltage detection method. For example, a voltage detection circuit is provided to detect the voltages of two connection nodes of the switch module connected to the power loop circuit, that is, the voltages at non-common nodes of the first transistor and the second transistor. If a voltage difference between the two nodes is less than a voltage threshold, the switch module is turned off. Here, the voltage threshold can be zero or close to zero. If the voltage difference between the two nodes approaches zero, it is considered that the current in the power loop circuit reaches the extremum. In this embodiment, the voltage detection method is more convenient and direct, but it requires higher accuracy in voltage detection.

Finally, the present disclosure further proposes a circuit system for receiving an AC input and forming a power loop circuit to supply power to an electrical device. The circuit system includes the above-mentioned power grid switching circuit. The circuit system can generate a turn-on enable signal/turn-off enable signal based on a working state of the system, such as a need for power on or off. The power grid switching circuit performs a switching operation based on the turn-on enable signal/turn-off enable signal. The circuit system of the present disclosure replaces a traditional mechanical switch with a transistor switch module, which achieves safe on/off with low-power consumption. The circuit system can be well applied in various power grid switching lines, achieving safe and efficient effects.

It should be additionally noted that the provided specific implementation and corresponding legends are only one way to describe the implementation method of the present disclosure, and do not limit a specific structure of the implementation solution of the present disclosure. Various changes or modifications can be made to these implementations without departing from the principle and essence of the present disclosure, but all these changes and modifications shall fall within the protection scope of the present disclosure.

Although the embodiments are separately illustrated and described above, the embodiments contain some common technologies. Those skilled in the art can replace and integrate the embodiments. Any content not clearly recorded in one of the embodiments may be determined based on another embodiment where the content is recorded.

The implementations described above do not constitute a limitation on the protection scope of the technical solution of the present disclosure. Any modification, equivalent replacement, and improvement made in the spirit and principle of the above implementations should fall in the protection scope of the technical solution of the present disclosure.

What is claimed is:

1. A power grid switching circuit, wherein an alternating current (AC) input is provided to supply power to an electrical device through a switch module and a current transformer; and the power grid switching circuit comprises:
an on-off control module, configured to output an on/off control signal to control an on/off state of the switch module;
wherein the switch module, the current transformer, and the electrical device form a power loop circuit when the switch module is in an on state; and the on-off control module is configured to control the switch module to turn off at a current extremum of the power loop circuit to disconnect the power loop circuit; and
the current extremum is zero or close to zero.

2. The power grid switching circuit according to claim 1, wherein the switch module comprises a field-effect transistor (FET) or bipolar transistor device.

3. The power grid switching circuit according to claim 1, wherein the on-off control module comprises a current detection circuit; the current detection circuit is configured to detect a current at a node in the power loop circuit; and when the current detected reaches the current extremum, the switch module is turned off.

4. The power grid switching circuit according to claim 1, wherein the on-off control module comprises a voltage detection circuit; the voltage detection circuit is configured to detect voltages at two connection nodes of the switch module connected to the power loop circuit; and when a voltage difference between the two connection nodes is less than a voltage threshold, the switch module is turned off.

5. The power grid switching circuit according to claim 1, wherein the switch module comprises a first transistor and a second transistor connected in series; and body diode directions of the first transistor and the second transistor are opposite; and
the on-off control module is configured to control a finally disconnected transistor of the first transistor and the second transistor to turn off at the current extremum to disconnect the power loop circuit.

6. The power grid switching circuit according to claim 5, wherein the on-off control module is configured to control the first transistor to turn off when receiving a turn-off enable signal and control the second transistor to turn off at the current extremum.

7. The power grid switching circuit according to claim 6, wherein when the on-off control module controls the first transistor to turn off, the second transistor remains on; and
the AC input forms the power loop circuit through the second transistor, a parasitic diode of the first transistor, the current transformer, and the electrical device; and when a current in the power loop circuit reaches the current extremum, the on-off control module controls the second transistor to turn off.

8. The power grid switching circuit according to claim 6, wherein the on-off control module comprises a first on-off control circuit and a second on-off control circuit;
the first on-off control circuit is configured to generate a first on/off signal based on a first node voltage and a first reference voltage to control an on/off state of the first transistor;
the second on-off control circuit is further configured to generate a second on/off signal based on a second node voltage and a second reference voltage to control an on/off state of the second transistor; and
a first terminal of the first transistor connected to a first terminal of the second transistor serves as a common connection terminal; and a voltage at a second terminal of the first transistor serves as the first node voltage, while a voltage at a second terminal of the second transistor serves as the second node voltage.

9. The power grid switching circuit according to claim 8, wherein the common connection terminal of the first transistor connected to the second transistor is connected to a reference ground terminal;
the first reference voltage is set to be less than a voltage of the reference ground terminal; and
the second reference voltage is set to be larger than the voltage of the reference ground terminal.

10. The power grid switching circuit according to claim 8, wherein
the first on-off control circuit comprises a first error circuit and a first switch; the first error circuit is configured to receive the first node voltage and the first reference voltage and generate a first error signal; and the first switch is turned on when the turn-off enable signal is valid; and
the second on-off control circuit comprises a second error circuit and a second switch; the second error circuit is configured to receive the second node voltage and the second reference voltage and generate a second error signal; and the second switch is turned on when the turn-off enable signal is valid.

11. The power grid switching circuit according to claim 8, wherein
the first on-off control circuit comprises a first error circuit; the first error circuit is configured to receive the first node voltage and the first reference voltage and generate a first error signal; and the first error circuit starts working when the turn-off enable signal is valid; and
the second on-off control circuit comprises a second error circuit; the second error circuit is configured to receive the second node voltage and the second reference voltage and generate a second error signal; and the second error circuit starts working when the turn-off enable signal is valid.

12. The power grid switching circuit according to claim 8, wherein the first on-off control circuit comprises a first pull-down circuit, and the second on-off control circuit comprises a second pull-down circuit;
the first pull-down circuit is connected between an output terminal of the first on-off control circuit and a control terminal of the first transistor; and when a control terminal voltage of the first transistor is detected to drop to a threshold voltage, the first pull-down circuit is turned on; and
the second pull-down circuit is connected between an output terminal of the second on-off control circuit and a control terminal of the second transistor; and when a control terminal voltage of the second transistor is detected to drop to the threshold voltage, the second pull-down circuit is turned on.

13. The power grid switching circuit according to claim 8, wherein the first on-off control circuit comprises a first resistor network, and the second on-off control circuit comprises a second resistor network;
the first resistor network comprises a first resistor and a switch connected in series with the first resistor to form a first series branch, and the first series branch is connected in parallel with the first transistor;
the second resistor network comprises a second resistor and a switch connected in series with the second resistor to form a second series branch, and the second series branch is connected in parallel with the second transistor; and
when the first transistor is turned off, the switch connected in series with the second resistor is turned on; and when the second transistor is turned off, the switch connected in series with the first resistor is turned on.

14. The power grid switching circuit according to claim 5, wherein the on-off control module comprises a turn-on control circuit;
the turn-on control circuit is connected to control terminals of the first transistor and the second transistor; and the turn-on control circuit is configured to pull up control terminal voltages of the first transistor and the second transistor when receiving a turn-on enable signal to control the first transistor and the second transistor to turn on; and
the turn-on control circuit is further configured to stop the pull-up of the control terminal voltages of the first transistor and the second transistor when receiving a turn-off enable signal.

15. The power grid switching circuit according to claim 14, wherein the turn-on control circuit comprises a terminal voltage detection circuit; and
when the terminal voltage detection circuit detects that two power terminal voltages of the first transistor and/or the second transistor reach or approach a zero voltage value, the turn-on control circuit controls the first transistor and/or the second transistor to turn on.

16. The power grid switching circuit according to claim 5, wherein
the on-off control module is configured to control the first transistor and the second transistor to turn off at the current extremum when receiving a turn-off enable signal.

17. The power grid switching circuit according to claim 16, wherein when the on-off control module receives the turn-off enable signal,
after a control terminal voltage of the first transistor decreases, both the first transistor and the second transistor remain on; and
the AC input forms the power loop circuit through the second transistor, the first transistor, the current transformer, and the electrical device; and when a current in the power loop circuit reaches the current extremum and a control terminal voltage of the second transistor decreases, the on-off control module controls the first transistor and the second transistor to turn off.

18. A circuit system, configured to receive an AC input and form a power loop circuit to supply power to an electrical device, and comprising the power grid switching circuit according to claim 1, wherein
the circuit system is configured to generate a turn-on enable signal/turn-off enable signal based on a working state of the circuit system, wherein the power grid switching circuit performs a switching operation based on the turn-on enable signal/turn-off enable signal.

19. The circuit system according to claim 18, wherein in the power grid switching circuit, the switch module comprises a FET or bipolar transistor device.

20. The circuit system according to claim 18, wherein in the power grid switching circuit, the on-off control module comprises a current detection circuit; the current detection circuit is configured to detect a current at a node in the power loop circuit; and when the current detected reaches the current extremum, the switch module is turned off.
